(19) United States
(12) Patent Application Publication
(10) Pub. No.: US 2026/0341956 A1
(43) Pub. Date: Oct. 29, 2026

(54) LOW LOSS IMPEDANCE ADAPTER DEVICE FOR COMPACT VEHICLE ANTENNA

(71) Applicant: ELETTRONICA MARRITTIMA S.R.L., San Lazzaro di Savena (IT)

(72) Inventors: Enrico Ghezzo, Ferrara (IT); Antonello Giovannelli, Ferrara (IT)

(21) Appl. No.: 19/111,022

(22) PCT Filed: Sep. 12, 2023
(86) PCT No.: PCT/IB2023/059031

§ 371 Date: Mar. 12, 2025

(30) Foreign Application Priority Data
Sep. 12, 2022 (IT) 102022000018510

(51) Int. Cl. H01Q 1/32; H01Q 9/30; H01Q 19/02; H01Q 19/10

(52) U.S. Cl. CPC H01Q 1/32; H01Q 9/30; H01Q 19/025; H01Q 19/10

(57) ABSTRACT

A low-loss impedance matching device (1) is shown as a part of a compact VHF band vehicular antenna (100).

The impedance matching device (1) includes: a transformer circuit (4), having its primary winding connected to the input terminal (102) and its secondary winding connected to the radiating element (101) and includes a plurality of binocular ferromagnetic cores (41), each core comprising a pair of through holes, first (41a) and second (41b), substantially parallel to each other. The transformer circuit (4) further includes a coaxial cable (5) segment, inserted into the first through-hole (41a) of each of the binocular ferromagnetic cores (41), leaving each of the second through-holes (41b) free. The device 1 further includes an electrical bypass circuit (6), aimed at progressively and automatically excluding the transformer circuit (4) from the antenna circuit in a highest frequency part of an operating frequency band of the antenna itself (100).

### TECHNICAL FIELD

The present invention relates to the technical field regarding transceiver antennas for professional use for terrestrial communications in the VHF (“Very High Frequency”) band, and more precisely to the type of so-called “short” stylus antennas.

In particular, the invention relates to a low-loss impedance matching device interposed between the antenna and the relative radio frequency (RF) transceiver equipment.

### BACKGROUND ART

Antennas that are suitable for operating in the VHF frequency band, which covers a frequency range extending approximately between 30 MHz and 300 MHz, are often made with a linear conductor (stylus), the dimensions of which are smaller than those for the electrical resonance of the stylus at the mid-frequency of use, and which corresponds, in “monopole” antennas, to a quarter-wave of the RF carrier. This is especially the case for antennas that must operate at the lower end of this band, at frequencies below a few tens of MHz, as the length of the stylus should be several meters, which is almost always impractical and essentially unfeasible for specific uses, such as vehicular.

For this reason, short stylus antennas are generally used in vehicular applications and for all other uses where compactness of the antenna is desired, in which the length of the stylus is equal to what would be the resonance length, i.e. a quarter of the wavelength of the antenna's operating mid-frequency.

### TECHNICAL PROBLEM

Such antennas solve the problem of vehicular use but have the defect of an impedance to the transceiver that is higher than the nominal 50 Ohm required by the latter.

To solve the impedance matching problem, an impedance matching circuit is normally used, which makes use of a transformer, or autotransformer, installed at the base of the antenna and interposed between the antenna and the transceiver equipment.

The matching transformer is generally made from a ferrite toroid onto which a suitable number of turns of electrical conductors are wound, according to the well-known techniques that will not be detailed here. In particular, the electrical conductors are preferably made up of helix wound (‘twisted’) pairs of copper wires. Depending on the ratio of turns between primary and secondary windings of the transformer, an impedance transformation takes place, which is usually set to a 4:1 ratio. The transformer thus makes it possible to transform the impedance of about 200 Ohm of the antenna at lower frequencies into an impedance of about 50 Ohm opposed to the transceiver equipment.

Typical characteristic problems of traditional impedance matching solutions include:
high losses in terms of RF power, due to the resistive, and therefore dissipative, component of the material of which the ferromagnetic toroidal cores are made, resulting from the characteristics of the magnetization curve (hysteresis loop);
presence of the aforementioned transformer, and above all of its dissipative characteristics, over the entire operating band, rather than only over the fraction of band in which the impedance transformation must be performed. Indeed, it is well known that where the length of the antenna approximates the resonance length (for example, half the wavelength for dipole antennas), the impedance of the antenna returns to values close to the optimal of 50 Ohms.

### OBJECTS OF THE INVENTION

The principal object of the invention is to propose an impedance matching device for a compact antenna, and in particular for a short stylus antenna, capable of providing an impedance matching only in the portion of the operating band distant from the resonance frequency and of not intervening in the portion of the band close to the latter frequency, where the impedance transformation would produce a mismatch with respect to the already present 50 Ohm.

A further object of the invention is to propose an impedance matching device capable of reducing dissipative losses with respect to conventional matching devices.

These and other objects are fully achieved by means of a low loss impedance matching device which is part of a compact VHF band vehicular antenna. The antenna comprises a stylus whose length is shorter than the wavelength corresponding to its resonance frequency, intended to receive and send radio frequency signals to a transceiver equipment through at least one signal input terminal.

The impedance matching device is interposed between the stylus-shaped radiating element and the signal input terminal to match the impedance of the radiating element.

The impedance matching device comprises: a transformer circuit, having its primary circuit connected to the input terminal and its secondary circuit connected to the radiating element and comprising a plurality of binocular ferromagnetic cores, each of which comprises a pair of substantially parallel first and second through holes. The transformer circuit further comprises a coaxial cable segment, inserted into the first through-hole of each of the binocular ferromagnetic cores, leaving each of the second through-holes free. The device further comprises an electrical bypass circuit, aimed at progressively and automatically excluding the transformer circuit from the antenna circuit in the highest frequency part of the operating frequency band of the antenna.

### BRIEF DESCRIPTION OF THE DRAWINGS

The characteristics of the invention in question will be evident from the following description of an amplified portable transceiver apparatus, in accordance with the content of the claims and with the help of the enclosed drawings, in which:

FIG. 1 shows a schematic view of a compact VHF band stylus antenna which incorporates the impedance matching device according to the invention;

FIG. 2 shows an illustrative circuit diagram of the matching transformer and of the bypass circuit connected thereto;

FIG. 3 shows an equivalent circuit of the example circuit diagram of FIG. 2 at lower frequencies of the operating band;

FIG. 4 shows a first equivalent circuit of the example diagram in FIG. 2 at the highest frequencies of the operating band, with the matching transformer totally excluded;

FIG. 5 shows a second equivalent circuit for high frequencies, with the core of the matching transformer used as a segment of the transmission line.

### DESCRIPTION OF EMBODIMENTS OF THE INVENTION

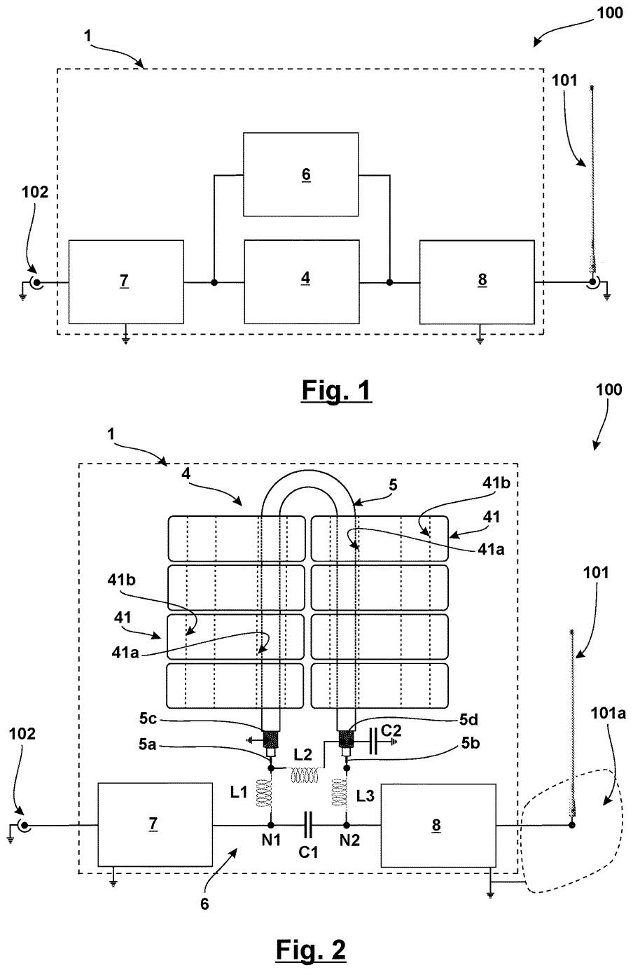

With reference to the aforementioned FIGS. 1 and 2, the reference number 100 indicates a compact VHF band antenna as a whole, thus intended to operate in a frequency band typically between 30 MHz and 100 MHz (corresponding to wavelengths of approximately between 10 meters and 3 meters), aimed at being connected to a transceiver equipment, not shown, and particularly suitable for vehicular use, especially, but not exclusively, in a military context.

The electrical configuration of antenna 100 is of the monopole type. This means that a linear radiating element 101 is provided, which electrically reflecting on a theoretically infinite ground plane 101a. In practice, in use, the ground plane generally comprises the metal surface, schematically illustrated in FIG. 2, of the vehicle on which the antenna 100 is installed.

The antenna 100 comprises substantially the aforementioned linear radiating element 101 having the form of a stylus (hereinafter referred to briefly as “stylus”), comprising a stem having a cylindrical or approximately cylindrical shape and a height considerably greater than its diameter, made of an electrically conducting material and preferably coated with a layer of polymeric material, aimed at giving it flexibility and greater resistance to atmospheric agents. An impedance matching device 1 made according to the present invention is connected to the stylus 101.

In particular, the term “compact antenna”, or “short antenna”, means that the length of the stylus 101, at least in the lower part of the frequency band of use, is shorter than its resonance length, and more precisely a length equal to ¼ of the wavelength.

It must be considered that for vehicular use, especially in complex use conditions as those to be faced in a military environment, it is important to make the stylus 101 as short as possible and as little as possible protruding from the vehicle footprint. In this way a radiating element is obtained whose main resonance frequency of antenna 100 is in the higher part of the frequency band of interest, usually around 100 MHz.

For this reason, in the absence of the impedance matching device 1, and especially in the lower part of the VHF frequencies, the antenna 100 would be strongly mismatched, i.e., it would have a considerably higher impedance than the 50 Ohm impedance required by the transceiver equipment.

The aforementioned matching device 1 is electrically connected to the stylus 1 and a radio frequency (RF) signal input terminal 102.

The RF input terminal 102 generally comprises a standard RF connector to which, in operating conditions, a coaxial signal transfer cable is suitably connected, which in turn is connected to the transceiver equipment.

Still with reference to FIGS. 1 and 2, the matching device 1 comprises a matching transformer circuit 4 and a bypass circuit 6, connected in an electrical parallel configuration, the structure and function of which will be better detailed later on, connected to the stylus 101 and to the RF input terminal 102 with the interposition of a pair of equalizer circuits, first 7 and second 8, of known type, realized with appropriate suitably sized passive LC networks. The only function of the latter is to compensate modest variations in impedance with respect to the optimal impedance, respectively to the input terminal 102 and with respect to the stylus radiating element 101. Their possible circuit configurations, as already anticipated, are well known and not relevant to the invention and therefore will not be discussed in further detail.

In particular, the primary circuit of the matching transformer circuit 4 is electrically connected to the aforementioned RF input terminal 102 and its secondary circuit is electrically connected to the stylus 101.

According to an advantageous aspect of the invention, the transformer circuit 4 is obtained by using a coaxial cable 5 segment having a predetermined length and preferably much less than ¼Λ (wavelength at the resonance frequency of the stylus 101). In general, it is preferable for the coaxial cable 5 length to be shorter than about 15 cm. According to well-known techniques, a coaxial cable segment, when inserted in a matching circuit, acts substantially like an autotransformer at the considered frequencies, and has a characteristic impedance of a suitable value, typically intermediate between the values occurring at the primary terminal and at the secondary terminal.

In this specific case, the optimum value is around 75 Ohm. Compared to the transformer circuits normally used in these applications and for VHF band frequencies, the use of coaxial cable instead of a pair of twisted wires is advantageous because of a known and repeatable impedance value, which would otherwise depend on the diameter of the conductors, the thickness and quality of the dielectric (sheath), and the pitch of the spiral coil formed by the winding of the two conductors.

With reference to FIG. 2, a first end 5a of the inner conductor (“core”) of the coaxial cable 5 is connected to the aforementioned first equalizer circuit 7, while a second end 5b of the same coaxial cable is connected to the aforementioned second equalizer circuit 8.

According to a further advantageous aspect of the invention, the transformer circuit 4 further comprises a plurality of substantially identical binocular ferromagnetic cores 41.

Each binocular core 41 comprises a block of ferromagnetic material, roughly formed as a rectangular parallelepiped, having two through holes, the first through hole 41a and the second through hole 41b, of equal diameter and substantially parallel to each other, to form a pair of hollow ferromagnetic elements.

Alternatively, the hollow ferromagnetic elements may have a cylindrical, toroidal or another conformation, advantageous from the point of view of increasing inductance seen in parallel with the primary winding.

The binocular ferromagnetic cores 41 may be preferably realized as a single body, or the hollow ferromagnetic elements may be realized separately and kept permanently juxtaposed by known techniques.

The transformer 4 illustrated in FIG. 1 uses, in not limiting way, eight binocular ferromagnetic cores 41 arranged consecutively on the coaxial cable 5; however, the use of a different number of binocular cores is to be considered within the scope of the invention.

According to a characterizing aspect of the invention, in the transformer circuit 4, the aforementioned coaxial cable 5 is inserted into the above mentioned first through-hole 41a of each binocular ferromagnetic core 41, whereas the second through-hole 41b of each of the binocular cores 41 is left free. The coaxial cable 5 is also folded in a “U” shape, mainly to optimize the space occupied by the transformer 4 and to facilitate the connection of the aforementioned bypass circuit 6 to the ends of the same coaxial cable 5.

The original configuration of the transformer circuit 4 described above allows to obtain at least two advantages, in comparison with the conventional configuration which uses binocular ferromagnetic cores. In fact, in the latter configuration the coaxial cable segment must be first inserted into one hole of all the binocular cores, then is folded into a “U” shape, and finally is inserted into the other hole of all the binocular cores, in the opposite direction. In this way, the magnetic fluxes induced in each binocular core tend to partially cancel each other out, thus resulting in a decrease of the obtained overall inductive value.

On the other hand, in the configuration obtained according to the present invention, using a single through-hole of each binocular core, and doubling the number of binocular cores used with the same length of coaxial cable, an increased magnetic induction flux within the binocular ferromagnetic core is obtained, compared to half the flux that would be obtained using both ferromagnetic elements of the same core, and a lower magnetic saturation of the cores is obtained. Furthermore, while requiring twice the number of binocular cores with respect to the conventional solution to achieve a not lower overall inductive value, the larger overall dissipative surface area and the presence of an unused cavity for each core significantly improves heat exchange with the environment, ensuring operation at lower temperatures than a conventional transformer.

Therefore, the transformer circuit 4 has lower power losses, and in any case the dissipated power is exchanged with the environment more efficiently, guaranteeing that the components operate at temperatures which are lower than average with the same power applied.

Since the impedance transformation carried out by the transformer circuit 4 is not required, or in any case is not desirable, at the highest frequencies of the operating band, according to the invention, the matching device 1 further comprises the aforementioned electrical bypass circuit 6, progressively self-operating, intended to progressively exclude the transformer 4 from the circuit at the highest frequencies of the operating band of the antenna 100, until it becomes invisible at the resonance frequency of the stylus 4, at which the impedance presented thereby is equal to or close to the nominal 50 Ohm.

In particular, the electrical bypass circuit 6 consists, in the most general, illustrative and non-limiting embodiment shown in FIG. 2, of a passive LC network whose components, in the illustrated example consisting of capacitors, first C1 and second C2, and inductors, first L1, second L2 and third L3, are suitably dimensioned depending on the operational curve to be obtained. In particular, the first capacitor C1 is connected, at the circuit nodes, first N1 and second N2, respectively, in parallel to the first 5a and second 5b ends of the inner conductor (“core”) of the coaxial cable 5 segment with the interposition of inductors, first L1 and third L3 in series, respectively; the second capacitor C2 is connected between a second end 5d of the mesh of twisted wires (‘sock’, which forms the screen conductor of the core) of the same coaxial cable 5 and the ground of the circuit; the second inductor L2 is connected between the aforesaid first end 5a of the core and second end 5d of the sock. The opposite end 5c of the sock is appropriately connected to the ground of the circuit.

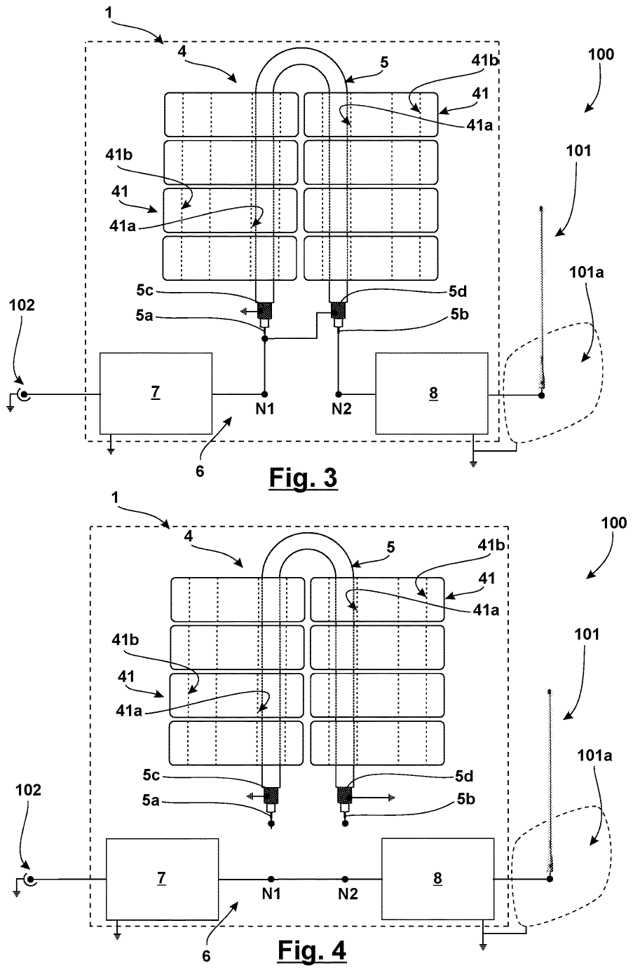

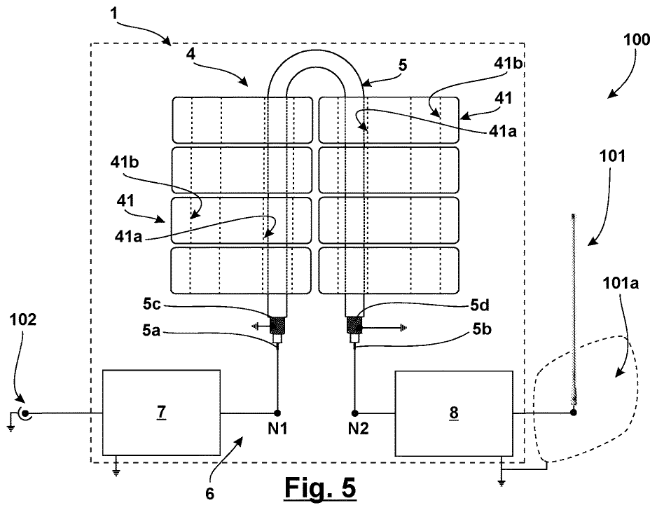

From a functional point of view, the electrical bypass circuit 6 operates exploiting the frequency-dependent behavior of its capacitive component and its inductive component, which, as already mentioned, are suitably dimensioned according to the thresholds and the progressivity of the operation. In particular, at lower frequencies of the band, the inductive component in series tends to approximate a short circuit, while the capacitive component in series approximates an open circuit (see the equivalent circuit for low frequencies in FIG. 3). At higher frequencies of the band, the inductive component in series tends to approximate an open circuit, while the capacitive component in series approximates a short circuit. In the more general circuit configuration shown in FIG. 2, the total exclusion of the transformer circuit 4 is therefore achieved (see the equivalent circuit for high frequencies in FIG. 4). Moreover, depending on particular requirements, other circuit configurations for the bypass circuit 6 make it possible to use the core of the coaxial cable 5 exclusively as a transmission line segment, as illustrated in the equivalent circuit for high frequencies in FIG. 5. It is understood that what is described above is illustrative and not limiting, therefore any detail variations that may be necessary for technical and/or functional reasons are considered within the same protection scope defined by the claims below.

1. A low-loss impedance matching device (1) for a compact VHF band vehicular antenna (100), said compact VHF band vehicular antenna (100) comprising a radiating element (101) of a stylus type, having a length shorter than a wavelength corresponding to a resonance frequency of the antenna, the vehicular antenna (100) configured to detect a radio frequency electromagnetic field, convert the field into corresponding incoming electrical signals and make said incoming electrical signals available to a transceiver equipment through at least one signal input terminal (102), and further configured to alternatively receive from the transceiver equipment outgoing electrical signals through said signal input terminal (102) and to generate a corresponding radiating electromagnetic field, said impedance matching device (1) configured for interconnection between said radiating element (101) and said signal input terminal (102) to match an impedance of said radiating element (101), wherein said impedance matching device (1) comprises:
a transformer circuit (4), including
a coaxial cable (5) segment including a primary circuit connected to said input terminal (102) and a secondary circuit connected to said radiating element (101) and
a plurality of binocular ferromagnetic cores (41), each comprising a pair of through holes, including a first through hole (41a) and a second through hole (41b) substantially parallel to the first through hole; said coaxial cable (5) segment inserted into said first through-hole (41a) of each of said binocular ferromagnetic cores (41), leaving free each of said second through-hole (41b); said impedance matching device (1) further comprising
an electrical bypass circuit (6), aimed at progressively and automatically excluding said transformer circuit (4) from the compact VHF band antenna (100) in a highest frequency part of an operation frequency band of said compact VHF band antenna

(100) .

2. The impedance matching device according to claim 1, further comprising a first equalizer circuit (7), interconnected between said input terminal (102) and said transformer circuit (4), and a second equalizer circuit (8), interconnected between said transformer circuit (4) and said radiating element (101).

3. The impedance matching device according to claim 1, wherein a first end (5a) of said inner conductor of said coaxial cable (5) of said transformer circuit (4) is electrically connected to said input terminal (102), and a second end (5b) of said inner conductor is electrically connected to said radiating element (101).

4. The impedance matching device according to claim 1, wherein said electrical bypass circuit (6) comprises an LC circuit dimensioned according to a selected operational curve.
